(19) United States
(12) Patent Application Publication
(10) Pub. No.: US 2007/0045863 A1
(43) Pub. Date: Mar. 1, 2007

(54) PACKAGE STRUCTURE AND FABRICATION PROCESS THEREOF

(76) Inventors: Ya-Yu Hsieh, Kaohsiung County (TW); Wei-Chung Wang, Kaohsiung County (TW); Tzu-Bin Lin, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,099

(22) Filed: Dec. 16, 2005

(30) Foreign Application Priority Data
Aug. 24, 2005 (TW) 94128878

(51) Int. Cl. H01L 23/52

(52) U.S. Cl. 257/777

(57) ABSTRACT

A packaging process including the following steps is provided. First, a first substrate and a second substrate are provided. The first substrate has first contacts, and the second substrate has second contacts. Next, the first substrate is placed on the second substrate, such that the first contacts are aligned with the second contacts. Then, the first substrate and the second substrate are submerged in a solution having BDMT. After that, the first substrate and the second substrate are removed from the solution, such that self-assembly mono-layers are formed between the first substrate and the second substrate, to electrically connect the first substrate and the second substrate. A package structure formed according to the above process is also provided.

### CROSS-REFERENCE TO RELATED APPLICATION

This application claims the priority benefit of Taiwan application serial no. 94128878, filed on Aug. 24, 2005. All disclosure of the Taiwan application is incorporated herein by reference.

### BACKGROUND OF THE INVENTION

1. Field of the Invention

The present invention generally relates to a package structure and a packaging process of an electronic device; more particularly, to a packaging structure having self-assembly mono-layers and a fabrication process thereof.

2. Description of Related Art

In today's highly advanced telecommunication society, the chip structure has developed to incorporate high processing speed, multi-function, high integration, small volume, light weight, and low cost, in response to the trend of digitalization, network application, local network connectivity, and user-friendliness in the electronic equipment. However, when the chip structure is developing towards miniaturization and integration, the pitch between every two neighboring bonding pads of the chip is accordingly decreased. Therefore, the conventional soldering technique is not suitable for electrically connecting a chip to a package substrate.

Therefore, a soldering method was disclosed to electrically connect a chip to a package substrate. First, a solder mask layer is formed on an active surface of the chip, wherein the solder mask layer has a plurality of openings for exposing a plurality of corresponding bonding pads. After that, a plurality of bumps are formed on the corresponding bonding pads through the openings, wherein the bumps are made of a metal material having a lower melting point.

Next, the chip is placed on a package substrate, such that the bumps are disposed between the chip and the package substrate, and the chip is aligned with the package substrate. A high-temperature reflow process is performed on the bumps at a suitable temperature according to the characteristics of the metal material, to form the electrical connection between the chip and the package substrate. The reflow temperature is between 100° C. and 200° C. Since the bumps are made of a metal material, this soldering method can enhance the bonding strength and signal transmission between the chip and the package structure.

However, concentrated heat often occurs on the chip or the package substrate due to their geometric shapes, border conditions or other factors during the high temperature reflow process, such that the heat is accumulated on some specific regions of the chip or the package substrate, wherein the temperature of the specific regions is higher than the predetermined temperature of the reflow process. Once the temperature of the specific regions is too high, the chip or the package structure would be damaged. Besides, residual stress can easily take place at the bonding regions between the bumps and the chip, or the bumps and the package substrate due to heat accumulation.

Furthermore, another adhesive method for electrically connecting a chip and a package structure was also disclosed. First, a conductive polymer material is formed on the bonding pads of the chip. Then, the chip is placed on the package substrate, such that the polymer material is disposed between the chip and the package substrate. Next, the chip is aligned with the package substrate. After the chip is aligned with the package substrate, the polymer material is cured or exposed to the ultraviolet (UV) light. Then, a cross-linking reaction occurs in the polymer material, thus making the chip electrically connected to the package substrate.

Note that compared with the high temperature reflow process, the cross-linking reaction occurs at a lower temperature. Preferably, when the polymer material is exposed to the UV light, the cross-linking reaction is completed in room temperature. Therefore, compared with the above-mentioned soldering method, this method can avoid the damages inflicted upon the chip or the package substrate due to the high-temperature thermal treatment process. Besides, this method also can avoid the residual stress generated at the bonding regions between the bumps and the chip, or the bumps and the package substrate due to heat accumulation.

Although the adhesive method has the above-mentioned advantages, it can not combine the bonding strength and electrical characteristics between the chip and the package substrate since the polymer material is inferior to the metal material in terms of structure strength and conductivity.

### SUMMARY OF THE INVENTION

Accordingly, the present invention is directed to providing a package structure having better bonding strength and electrical characteristics.

The present invention is also directed to a low-temperature chip packaging process.

As embodied and broadly described herein, the present invention provides a package structure comprising a first substrate, a second substrate and a plurality of self-assembly mono-layers. The first substrate comprises a plurity of first contacts, and the second substrate comprises a plurality of second contacts. The self-assembly mono-layers are disposed between the first contacts and the second contacts.

According to an embodiment of the present invention, the first substrate comprises a circuit board or a chip, and the second substrate comprises a circuit board or a chip.

According to an embodiment of the present invention, a material of the monolayer comprises benzene-1,4-dithiol.

As embodied and broadly described herein, the present invention also provides a packaging process comprising the following steps. First, a first substrate and a second substrate are provided, wherein the first substrate comprises a plurality of first contacts, and the second substrate comprises a plurality of second contacts. Next, the first substrate is placed on the second substrate, such that the first contacts are aligned with the second contacts. Then, the first substrate and the second substrate are submerged in a solution having 1,4-benzenedimethanethiol. After that, the first substrate and the second substrate are removed from the solution, such that a plurality of self-assembly mono-layers are formed between the first contacts and the second contacts, to electrically connect the first contacts and the second contacts.

According to an embodiment of the present invention, the solution comprises tetrahydrofuran (THF).

According to an embodiment of the present invention, after the step of removing the first substrate and the second substrate from the solution, the first substrate and the second substrate are placed under an argon atmosphere, to evaporate the tetrahydrofuran.

According to an embodiment of the present invention, the self-assembly mono-layers are formed at room temperature.

As embodied and broadly described herein, the present invention also provides a packaging process comprising the following steps. First, a first substrate and a second substrate are provided, wherein the first substrate comprises a plurality of first contacts, and the second substrate comprises a plurality of second contacts. Then, the first substrate and the second substrate are submerged in a solution having 1,4-benzenedimethanethiol. Next, the first substrate is placed on the second substrate, to make the first contacts align with the second contacts. After that, the first substrate and the second substrate are removed from the solution, such that a plurality of self-assembly mono-layers are formed between the first contacts and the second contacts, to electrically connect the first contacts and the second contacts.

According to an embodiment of the present invention, the solution comprises tetrahydrofuran (THF).

According to an embodiment of the present invention, after the step of removing the first substrate and the second substrate from the solution, the first substrate and the second substrate are placed under an argon atmosphere, to evaporate the tetrahydrofuran.

According to an embodiment of the present invention, the self-assembly mono-layers are formed at room temperature.

As embodied and broadly described herein, the present invention further provides a packaging process comprising the following steps. First, a first substrate and a second substrate are provided, wherein the first substrate comprises a plurality of first contacts, and the second substrate comprises a plurality of second contacts. Then, a plurality of thin film particles of self-assembly monolayer are formed on the first contacts and the second contacts. Finally, the first substrate is placed on the second substrate, and the first contacts are aligned with the second contacts, such that a plurality of self-assembly mono-layers are formed between the first contacts and the second contacts, to electrically connect the first contacts and the second contacts.

According to an embodiment of the present invention, the method of forming the thin film particles of self-assembly mono-layer on the first contacts and the second contacts comprises a sputtering process.

The present invention is to form the self-assembly mono-layers between the first contacts and the second contacts at room temperature, to electrically connect the first substrate and the second substrate. Therefore, the concentrated heat and residual stress can be avoided during the fabrication process. Besides, the package structure has a higher bonding strength between the first substrate and the second substrate and better electrical characteristics since the self-assembly mono-layers have better mechanical strength and conductivity.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1C are schematic cross-sectional diagrams illustrating a packaging process flow according to an embodiment of the present invention.

FIG. 1D is a schematic cross-sectional diagram illustrating a step of evaporating TFT.

FIGS. 2A to 2C are schematic cross-sectional diagrams illustrating a packaging process flow according to another embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

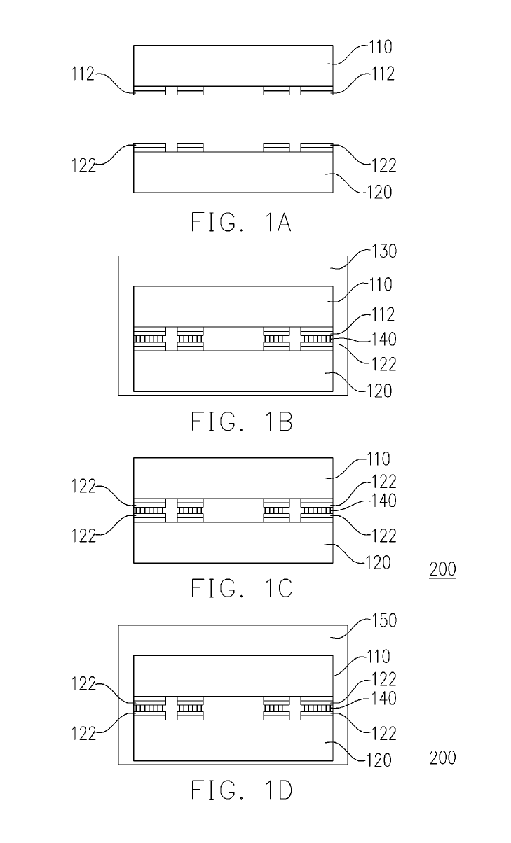

FIGS. 1A to 1C are schematic cross-sectional diagrams illustrating a packaging process flow according to an embodiment of the present invention. Please refer to FIG. 1A. A first substrate 110 and a second substrate 120 are provided first, wherein the first substrate 110 has a plurality of first contacts 112 and the second substrate 120 has a plurality of second contacts 122. In this embodiment, the first substrate 110 can be a chip, and the second substrate 120 can be a circuit board. Of course, the first substrate 110 can be either a and or a circuit board, and the second substrate 120 can either be a chip or a circuit board in another embodiment. Besides, the first contacts 112 and the second contacts 122 can be made of Au/Cr.

Next, please refer to FIG. 1B. The first substrate 110 is placed on the second substrate 120, such that the first contacts 112 and the second contacts 122 are disposed between the first substrate 110 and the second substrate 120. In the meantime, the first substrate 110 is aligned with the second substrate 120, to make the first contacts 112 align with the second contacts 122. In this embodiment, after the first substrate 110 is aligned with the second substrate 120, a clamping apparatus can be used to clamp the first substrate 110 and the second substrate 120 together to fix the relative position between the first substrate 110 and the second substrate 120.

Please refer to FIG. 1B. After the first substrate 110 is aligned with the second substrate 120, the first substrate 110 and the second substrate 120 are submerged in a solution 130 having 1,4-benzenedimethanethiol (BDMT). In this embodiment, the solution 130 can be tetrahydrofuran (THF) or the like, and this step is performed at room temperature.

Besides, in addition to the above-mentioned method, the first substrate 110 and the second substrate 120 can be submerged in the solution 130 having 1,4-benzenedimethanethiol(BDMT) directly, and the first substrate 110 is aligned with the second substrate 120.

Please refer to FIG. 1C. After the first substrate 110 and the second substrate 120 are submerged in the solution 130 for a suitable period of time, the first substrate 110 and the second substrate 120 are removed from the solution 130, such that a plurality of self-assembly mono-layers 140 are formed between the first contacts 112 and the second contacts 122, to electrically connect the first contacts 112 and the second contacts 122, thus forming a package structure 200.

Preferably, the solution 130 can be removed from the package structure 200 as shown in FIG. 1D. Please refer to FIG. 1D. After the package structure 200 is removed from the solution 130, the package structure 200 can be placed under an argon atmosphere 150, to evaporate TFT gradually.

The present invention further provides a package structure 200 according to the above process. Again, please refer to FIG. 1C. The package structure 20 mainly comprises a first substrate 110, a second substrate 120 and a plurality of self-assembly mono-layers 140. The first substrate 110 has a plurality of first contacts 112, and the second substrate 120 has a plurality of second contacts 122. The self-assembly mono-layers 140 are disposed between the first contacts 112 and the second contacts 122.

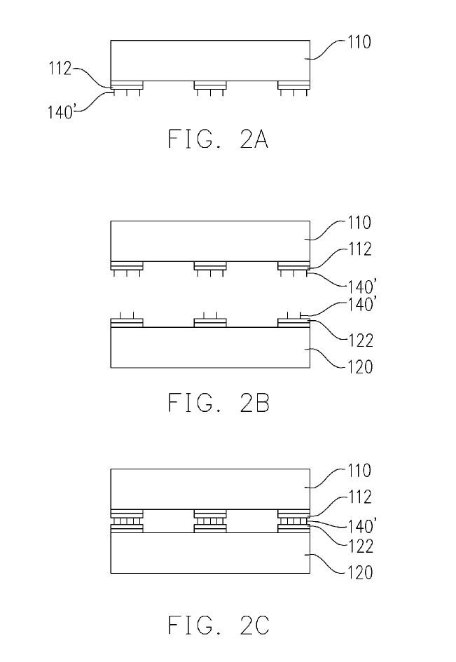

FIGS. 2A to 2C are schematic cross-sectional diagrams illustrating a packaging process flow according to another embodiment of the present invention. First, please refer to FIG. 2A. A first substrate 110 is provided, and the first substrate 110 has a plurality of first contacts 112. Next, a plurality of thin film particles of self-assembly mono-layer 140′ are formed on the first contacts 112 by sputtering. Preferably, the sputtering process can be performed in a chamber (not shown) filled with inert gas, and the inert gas can be nitrogen.

Please refer to FIG. 2B. A second substrate 120 is provided. The second substrate 120 has a plurality of second contacts 122. Then, a plurality of thin film particles of self-assembly mono-layer 140′ are formed on the second contacts 122 by using the same method.

Next, please refer to FIG. 2C. The first substrate 110 is aligned with the second substrate 120, to make the first contacts 112 align with the second contacts 122. Therefore, a plurality of self-assembly mono-layers 140 disposed between the first contacts 112 and the second contacts 122 are formed by the thin film particles of self-assembly mono-layer 140′, and the self-assembly mono-layers 140 are adapted for electrically connecting the first contacts 112 and the second contacts 122.

In summary, the present invention is to form the self-assembly mono-layers between the first contacts and the second contacts at room temperature, to electrically connect the first substrate and the second substrate. Compared with the prior art, in the present invention, the electrical connection between the first substrate and the second substrate is achieved without a high-temperature process (such as a reflow process), and therefore heat concentration would not occur in the first substrate or the second substrate, thus avoiding the damages in the first substrate or the second substrate. In the meantime, residual stress at where the first contacts or the second contacts meet the self-assembly mono-layers can be avoided.

Besides, the package structure has higher bonding strength between the first substrate and the second substrate and better electrical characteristics since the self-assembly mono-layers have better mechanical strength and conductivity.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A package structure, comprising:
a first substrate, comprising a plurality of first contacts;
a second substrate, comprising a plurality of second contacts; and
a plurality of self-assembly mono-layers, disposed between the first contacts and the second contacts.

2. The package structure according to claim 1, wherein the first substrate comprises a circuit board or a chip, and the second substrate comprises a circuit board or a chip.

3. The package structure according to claim 1, wherein a material of the monolayer comprises benzene-1,4-dithiol.

4. A packaging process, comprising:
providing a first substrate and a second substrate, wherein the first substrate comprises a plurality of first contacts, and the second substrate comprises a plurality of second contacts;
placing the first substrate on the second substrate, such that the first contacts are aligned with the second contacts;
submerging the first substrate and the second substrate in a solution having 1,4-benzenedimethanethiol; and
removing the first substrate and the second substrate from the solution, such that a plurality of self-assembly mono-layers are formed between the first contacts and the second contacts, to electrically connect the first contacts and the second contacts.

5. The packaging process according to claim 4, wherein the solution comprises tetrahydrofuran (THF).

6. The packaging process according to claim 5, wherein after the step of removing the first substrate and the second substrate from the solution, the first substrate and the second substrate are placed under an argon atmosphere, to evaporate the tetrahydrofuran.

7. The packaging process according to claim 4, wherein the self-assembly mono-layers are formed at room temperature.

8. A packaging process, comprising:
providing a first substrate and a second substrate, wherein the first substrate comprises a plurality of first contacts, and the second substrate comprises a plurality of second contacts;
submerging the first substrate and the second substrate in a solution having 1,4-benzenedimethanethiol;
placing the first substrate on the second substrate, to make the first contacts align with the second contacts; and
removing the first substrate and the second substrate from the solution, such that a plurality of self-assembly mono-layers are formed between the first contacts and the second contacts, to electrically connect the first contacts and the second contacts.

9. The packaging process according to claim 8, wherein the solution comprises tetrahydrofuran (THF).

10. The packaging process according to claim 9, wherein after the step of removing the first substrate and the second substrate from the solution, the first substrate and the second substrate are placed under an argon atmosphere, to evaporate the tetrahydrofuran.

11. The packaging process according to claim 8, wherein the self-assembly mono-layers are formed at room temperature.

12. A packaging process, comprising:
providing a first substrate and a second substrate, wherein the first substrate comprises a plurality of first contacts, and the second substrate comprises a plurality of second contacts;
forming a plurality of thin film particles of self-assembly mono-layer on the first contacts and the second contacts; and
placing the first substrate on the second substrate and making the first contacts align with the second contacts, such that a plurality of self-assembly mono-layers are formed between the first contacts and the second contacts, to electrically connect the first contacts and the second contacts.

13. The packaging process according to claim 12, wherein the method of forming the thin film particles of self-assembly mono-layer on the first contacts and the second contacts comprises a sputtering process.
